(19) United States
(12) Patent Application Publication
(10) Pub. No.: US 2024/0347398 A1
(43) Pub. Date: Oct. 17, 2024

(54) MICROLED DEFECT MANAGEMENT

(71) Applicant: VueReal Inc., Waterloo (CA)

(72) Inventors: Gholamreza CHAJI, Waterloo (CA); Hossein Zamani SIBONI, Waterloo (CA)

(73) Assignee: VueReal Inc., Waterloo, ON (CA)

(21) Appl. No.: 18/292,645

(22) PCT Filed: Jul. 26, 2022
(86) PCT No.: PCT/CA22/51149

§ 371 Date: Jan. 26, 2024

Related U.S. Application Data
(60) Provisional application No. 63/225,804, filed on Jul. 26, 2021.

(51) Int. Cl. H01L 21/66; H01L 21/68; H01L 21/683; H01L 23/00; H01L 23/544

(52) U.S. Cl. CPC H01L 22/22; H01L 21/68; H01L 21/6835; H01L 23/544; H01L 24/98; H01L 2221/68363; H01L 2223/54406; H01L 2224/98; H01L 2924/12041

(57) ABSTRACT

The present invention discloses a method to manage defects in microdevice sets being transferred from a donor substrate to a system or temporary substrate. Various methods can identify the defects before and after the transfer, and rectifying mechanisms or steps are outlined. A key point is to adjust the transfer of a next set of microdevices based on data on defects.

### BACKGROUND AND FIELD OF THE INVENTION

The invention relates to a micro device transfer from a donor substrate to a system substrate.

### SUMMARY

The present invention relates to a method to manage defects in a micro device transfer process from a donor substrate. The method comprises aligning the donor substrate with a system or temporary substrate, inspecting the transferred microdevices for defects wherein the inspection is either visual, photo luminance, or electrical luminance, and identifying a defect type wherein defects are either missing devices, devices stock to the donor substrate permanently or devices that are not functional or have physical defects, rectifying the identified defect based on the protocol, transferring micro devices to the system substrate or temporary substrate, and offsetting the donor substrate to a next transfer position.

The present invention also relates to a method to manage defects in the micro device transfer process from a donor substrate to a system or temporary substrate, the method comprising aligning the donor substrate with a system or temporary substrate, transferring selected micro devices to the system or temporary substrate, bonding the transferred micro devices, inspecting the donor substrate for defects wherein the inspection is either visual, photo luminance, or electrical luminance, identifying a defect type wherein defects are either missing devices, devices stock to the donor substrate permanently or devices that are not functional or have physical defects, and rectifying the identified defect based on a protocol.

The present invention also relates to transferring micro devices from donor substrate into system substrate. The method comprises aligning a selected set of micro devices in the donor substrate to the system substrate, transferring the selected micro devices into the system substrate, inspecting transferred microdevices for defects, and rectifying the defects that interfere with any of the following transfer cycles before that transfer cycle.

The present invention also relates a method to manage defects in a microdevice transfer process from a donor substrate, comprising steps of transferring a set of microdevices to the system substrate or temporary substrate, inspecting the transferred microdevices for defects wherein the inspection is either visual, photo luminance, or electrical luminance, identifying a defect type wherein defects are either missing devices, devices stocked to the donor substrate permanently or devices that are not functional or have physical defects, rectifying the identified defect based on a protocol; and adjusting the transfer of a next set of microdevices to the system substrate or temporary substrate based on the protocol.

### BRIEF DESCRIPTION OF THE DRAWINGS

The preceding and other advantages of the disclosure will become apparent upon reading the following detailed description and reference to the drawings.

FIG. 1(a) shows a donor substrate with microdevices aligned with the system substrate.

FIG. 1(b) shows the microdevices transferred to the system substrate.

FIG. 2(a) shows a donor substrate with microdevices.

FIG. 2(b) shows defect removal.

FIG. 3 shows an embodiment of process steps to manage different defect types.

FIG. 4 shows an embodiment of active management of the defects after the transfer.

The present disclosure is susceptible to various modifications and alternative forms. Specific embodiments or implementations have been shown by example in the drawings and will be described herein. It should be understood, however, that the disclosure is not intended to be limited to the particular forms disclosed. Instead, the disclosure is to cover all modifications, equivalents, and alternatives falling within the spirit and scope of an invention as defined by the appended claims.

### DETAILED DESCRIPTION

The terms “device” and “micro-device” are used interchangeably in this description. However, it is apparent to one skilled in the art that the embodiments described here are independent of the device size.

A device such as a “Micro LED” is described. Micro LEDs are also known as micro-LED, mLED, or uLED. These devices consist of arrays of microscopic LEDs forming the individual pixel elements. These LEDs could be, for example, video-capable InGaN microLED that can be used to create a microdisplay in VGA format. Micro LEDs offer significantly reduced energy requirements compared to conventional LCDs while offering pixel-level light control and a high contrast ratio. The inorganic materials of micro-LEDs allow for a longer lifetime compared to OLEDs. MicroLEDS allows for brighter images with minimal risk of screen burn-in. The Micro LEDs have sub-nanosecond response times that have the advantage over other display technologies for 3D/AR/VR displays since these devices need more images, more pixels per image, more frames per second, and fast response.

The description identifies a method including various embodiments identified below to manage defects as part of micro device transfer.

One method of transferring micro devices to a system substrate includes a donor substrate that holds the microdevices temporarily.

A selected set of micro devices are aligned with the system substrate, and the selected set of micro devices is transferred into the system substrate. The system substrate has electrodes and pixel structure that enable driving the microdevices.

In one case, the system substrate can form a display, and micro devices are light emitting. In another case, the system substrate can form both a display and microdevices of light emitting devices as well as other integrated components, such as but not limited to, (1) memory, (2) processors, (3) other types of displays, (4) fuses, (5) sensors, (6) actuators, etc. In another related case, system substrates can include sensing pixels, and the microdevices can include sensors. The microdevices can also be chiplet, MEMS, and other optoelectronic, electrochemical, or electronic devices.

The process can be repeated to populate the system substrate with the microdevices. In another case, a second donor substrate with second micro devices is used to populate the second pixel or area system substrate. In another case, a third donor substrate with third micro devices is used to populate a third micro device area on the system substrate that could be the redundant microdevice to replace another non-working microdevice.

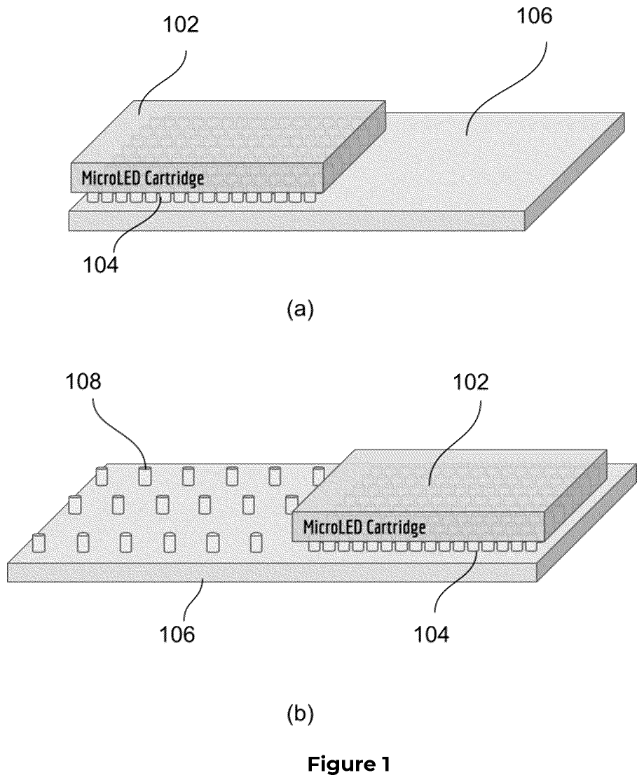

FIGS. 1 (1(a) and 1(b)) show the transfer process described here. In FIG. 1(a), donor substrate 102 includes micro devices 104, where it is aligned with the system substrate or temporary substrate 106.

In FIG. 1(b), the microdevices 108 get transferred to the system substrate 106. The donor substrate 102 is then offset to the next position. The process is repeated until the system substrate, or temporary substrate, is entirely populated, or the microdevices in the donor substrate are finished.

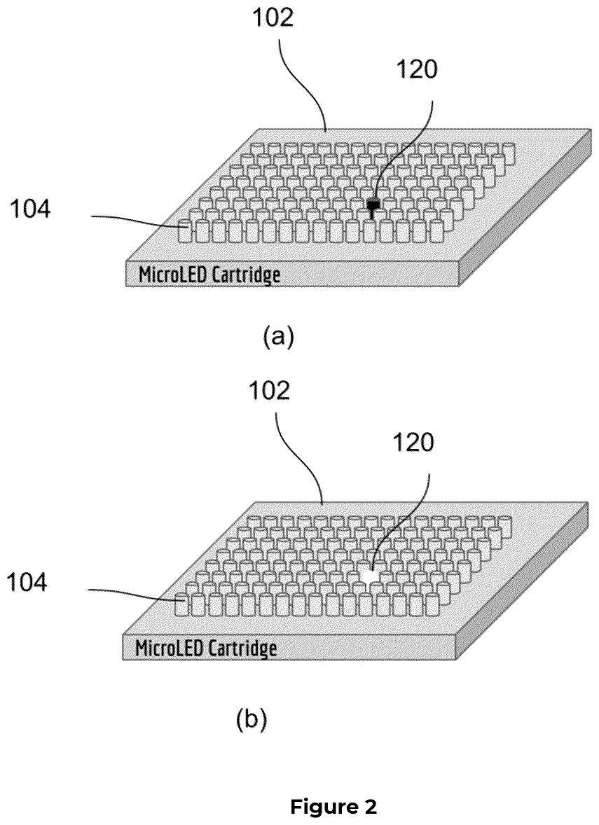

There can be defects in the donor substrate. FIG. 2(a) shows a donor substrate 102 with microdevices 104. There is a defect 120 in one of the devices. The defects can include a non-working pixel, a poorly working microdevice, a missing microdevice, a microdevice with foreign material, etc. The defect can be removed, as demonstrated in FIG. 2(b).

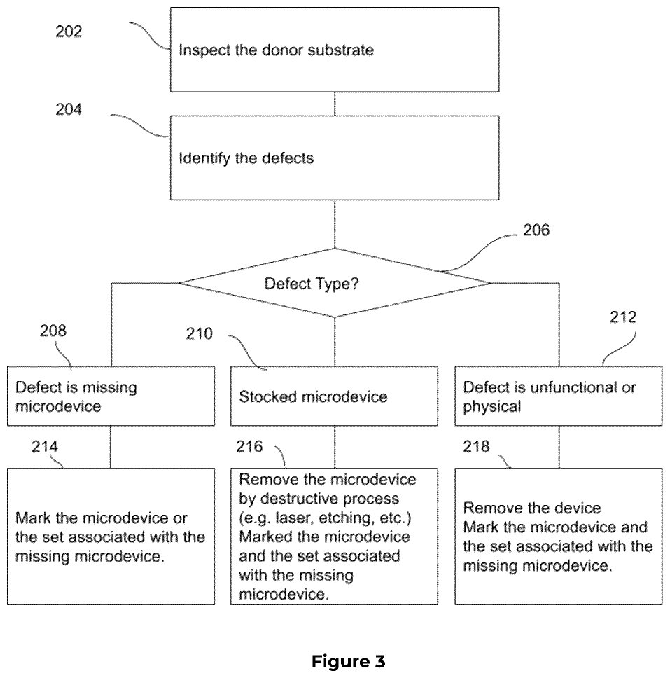

FIG. 3 shows an embodiment of process steps to manage different defect types 206. During the first step, 202, the donor substrate is inspected. Here the inspection can be visual, photo luminance, or electrical luminance. The inspection could be done by other means, for instance, electrical activation and readout of results electrically, e.g., opens or shorts, etc. The inspection data is used to identify defects in the donor substrate (step 204).

Defects can be identified on the donor substrate and could be, for example, used to determine whether or not to do the transference. That is, if there are more than five percent defects, the donor is not used to doing transference. The percentage defects threshold to use the donor substrate or not is based upon the standard procedures of looking at the total customer defect densities allowed and working thru the process defects averages of all the next steps of transference and beyond. The donor defect percentages are part of the defect densities measured and allowed.

The defects can be different types, such as missing devices, devices stuck to the donor substrate permanently, or devices that are not functional or have physical defects. The defects could be misaligned microdevices, partial pixels, or odd-shaped microdevices.

The defects are categorized in step 206 accordingly after identifying them in 204. The position can be marked if the defect is missing micro device 208. The device's position is marked in one related embodiment 214 of dealing with the missing microdevice. Here, when the set associated with the microdevice is transferred to the system substrate, there will be a known missing defect in the system substrate. In another case, the set associated with the missing micro device is marked, and during transfer, this set is not transferred and skipped. In one related case, the marked micro device set is removed in advance, so it does not interfere with the system backplane.

Any of several means can do the marking. In one example, the donor defect micro device address [row and column address] is stored so that later on, the system can use this defect data to determine how to add redundancy [turning in the neighboring microdevice to help mask the defective micro device] of neighboring pixels to the defective microdevice.

If the defect is stocked in micro device 210, in a related embodiment 216, the microdevice can be removed before transfer using destructive methods such as laser, etching, or other approaches. Here, the microdevice is marked as a missing microdevice and can be dealt with as described above. Another example of removing a microdevice could be to ablate the microdevice electrically.

If the defect is unfunctional or physical defect 212, the microdevice is either marked or removed 218. And after that, the same process as missing microdevice 214 described above can be used to deal with these defects.

After each transfer of micro devices from the donor substrate to the system substrate, defects may form on the system substrate and the donor substrate. To avoid interference between the new defects on the system substrate and donor substrate, a system needs to monitor and manage some defects before the subsequent transfer of the first microdevice for the second microdevice transfer from a second donor substrate. So, there in adjustment done before the next transfer of the next set of microdevices to the system substrate or temporary substrate based on the protocol.

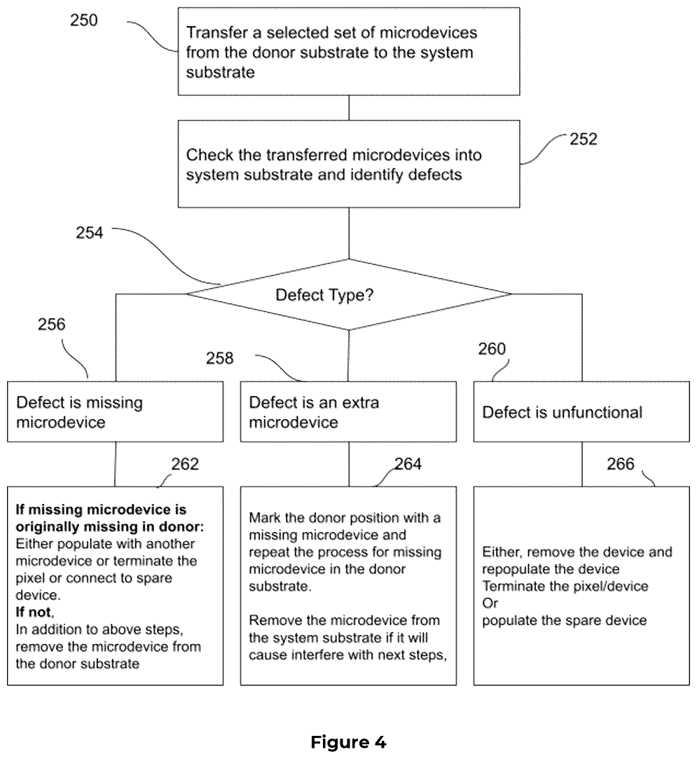

FIG. 4 shows an embodiment of active management of the defects after the transfer. During the first step, 250, a selected micro device is transferred from the donor substrate into the system substrate. Here the transfer can be done as described above. The devices can be permanently bonded to the system substrate or temporarily.

The permanent bonding could be done by use of a heat treatment to anneal electrical contacts. The permanent bonding could also be accomplished by depositing an optical coating film. The permanent bonding could also be accomplished through a final encapsulation step.

The temporary bonding allows correcting for some of the defects. During the second step, 252 the microdevices transferred to the system substrate are inspected. The inspection can be either visual, electrical, optoluminance, or other forms. The data collected during the inspection is used to identify the defects and type of defects 254.

If the defect is missing microdevice 256, the microdevice does not exist in the desired place in the system substrate. The process can be described in step 262. The missing microdevice can come from the donor substrate's missing microdevice. In this case, no action may be needed for the donor substrate. The microdevice in the system substrate can be populated with another microdevice, or it can be redirected to a spare microdevice. Or the pixel with the missing micro device is terminated. If the missing micro device is on the donor substrate, the microdevice or the microdevice set needs to be removed from the donor substrate before it may interfere with other parts of the system substrate or transferred microdevices. The removal process can be done by a spare backplane or other mechanical, laser, etc.

If the defect is extra microdevice 258, there is an extra microdevice in an unwanted area of the system substrate. The process of handling the different micro devices is described in step 264. The different device in the system substrate means a missing microdevice in the donor substrate. Therefore, the same process as the original missing micro device described in FIG. 3 and the above can be done for the donor substrate. Furthermore, the different microdevices can interfere with the subsequent transfers or backplane post-processing. Thus, it can be removed from the system substrate. The removal can be done by laser, elastomer, or other methods. Also, it can be done by pressurized gas (air) or liquid (water). As the different devices are not properly bonded to the system substrate, they can be cleared quickly with a pressurized carrier.

If the defect is nonfunctional or physical damage 260, the process of managing the defect is shown in step 266. Here the defective device can be removed and replaced with a working device. Or the pixel with a defective device can be terminated (either in the substrate by laser or other methods) or in the driving system by disabling the pixel in driving mode). The pixel can be redirected to or populated with a spare device in another related method.

The FIGS. 3 and 4 potentially outline a method to manage defects in a microdevice transfer process from a donor substrate, comprising steps of transferring a set of microdevices to the system substrate or temporary substrate, inspecting the transferred microdevices for defects wherein the inspection is either visual, photo luminance, or electrical luminance, identifying a defect type wherein defects are either missing devices, devices stocked to the donor substrate permanently or devices that are not functional or have physical defects, rectifying the identified defect based on a protocol; and adjusting the transfer of a next set of microdevices to the system substrate or temporary substrate based on the protocol.

The method also relates to manage defects in a microdevice transfer process from a donor substrate, the method comprising; inspecting the donor substrate to identify defects in the donor substrate wherein the defects are missing devices, permanently stocked devices to the donor substrate, non functional or physically damaged devices; transferring a set of microdevices from the donor substrate to the system substrate or temporary substrate; inspecting a first set of transferred microdevices for defects; identifying a defect type wherein defects are either missing devices, extra transferred microdevice or devices that are not functional or have physical defects; and using an inspection data from donor substrate and system substrate to (i) rectify the identified defect on system substrate; (ii) fix the donor substrate; and (iii) update the defect data for the donor substrate.

The method further elates to wherein the inspections are either visual, photo luminance, or electrical luminance and further wherein the defect in donor substrate is modified to missing defects based on inspection data and defect type prior to the transfer.

Here as well modifying the defect type includes if the defect type is: (i) missing devices: tag the position in donor substrate as missing devices; (ii) permanently stocked devices: remove the stocked devise with force and tag the position as missing devices; and (iii) unfunctional or physically damaged: remove the device and tag the position as missing devices.

Further, wherein rectifying defects in system substrate includes if the defect type is: (i) missing devices: tag the position as missing device and populate with new device at some point; (ii) extra device: remove the extra device; and (iii) unfunctional device: remove the device and tag the position as missing device and populate with a new device at some point.

Furthermore, updating donor inspection data based on system substrate inspection includes if the system substrate defect type is: (i) a missing defect: if the defect does not match existing missing device defects in the donor substrate, remove the device left in that position of donor substrate; and (ii) an extra device: tag the position in the donor substrate match the extra device with missing defect.

A further embodiment is a method to manage defects in a micro device transfer process from a donor substrate. The method inspects the transferred microdevices for defects wherein the inspection is either visual, photo luminance, or electrical luminance, and the identification of a defect type is made, wherein defects are either (1) missing devices, (2) devices stuck to the donor substrate permanently or (3) devices that are not functional or have physical defects; and rectifying the identified defect based on a protocol.

In one embodiment, the defective micro devices on the donor are stored in a database, and the pattern of the defective devices are classified by, for example, (1) shape, (2) region of the donor, (3) randomness, (4), etc. After the defects are removed, the final display defect densities are analyzed. A comparison is made to the results of the final defect densities and the donor defect densities and patterns. If some donor defect patterns or densities are found that relate to the final display being too high in defect densities, then any new donor substrates that have similar defect densities or patterns that would correlate to not achieving final display defect densities, then these new donor substrates with these correlated defective densities are deemed defective, and these donor substrates are discarded.

In one embodiment, visual inspections can be done in an automated method, by an automated high-powered microscope system that scans each microdevice. These images are stored by address [row and column], and each micro device image is compared to a standard library of images. The library of micro device images would have a quality scale for microdevices that meet or don't meet the quality required. So, the automated high-powered microscope system will output a report of the quality of each pixel.

In one embodiment, the automated high-powered microscope system can be used with a quality defect algorithm that will determine (1) if the donor substrates microdevice are ok as is, (2) if the donor substrate microdevices that are defective can be repaired, or (3) if the entire donor substrate is unusable.

In one embodiment, machine learning algorithms are used for quality inspections, and the automated high-powered microscope system learns over time by using historical data to final display quality data.

In one embodiment, photoluminescence can be a light emission from a micro device exposed to various light frequencies. For example, blue light can be emitted onto the donor substrate, and the automated high-powered microscope system can evaluate the optical response of each microdevice. Blue light may provide a detailed response to emissions from the microdevice. Also, red light and green light can be used. Also, white light can be used. Using multiple light sources and the automated high powered microscope system to see the response of each micro device, a high-quality response map of each donor substrate is determined. The quality response map is used to determine the final quality of the donor substrates. For instance, if a database is created of known defective micro devices, where each known defective and non-defective microdevices are exposed to various light sources, and a map of good and defective microdevices is collected against various light sources responses, then a database is created that can be used to determine the future quality of microdevices.

A further embodiment is a method wherein a transfer of donor substrates includes aligning a selected set of micro devices on the donor substrate with the system or temporary substrate and then transferring the selected set of micro devices to the system or temporary substrate; and offsetting the donor substrate to the next transfer position.

In one embodiment, each donor substrate is analyzed for its defective microdevices and subsequent marking or removal, and this information is stored in a database. An optimized placement algorithm determines which donor substrates can be placed next to other donor substrates based upon overall visual effects. For instance, a high-density defective microdevice may be less noticeable to a user if it is not next to a similar high-density defective microdevice.

In a further embodiment, the transfer method uses a micro devices donor substrate inspection prior to the next transfer. For example, a donor substrate is inspected optically to determine which microdevices are marked or removed. After a transfer, the microdevices transferred are optically inspected to compare which microdevices have been marked or removed from the donor substrate to the resultant transfer. If there is a one-to-one match, the transfer is deemed passed. If, however, there are new microdevices that are defective that were not on the donor substrate, then a transfer quality algorithm is used to determine if (1) the new defective microdevices can be marked or removed or repaired or (2) the new defective microdevices are so bad that a rework procedure is required. For example, the transfer quality algorithm will determine if newly defective microdevices are found adjacent to the original defective micro devices, these new defective microdevices are deemed as donor impacted defective, whereas if the newly defective microdevices are not near [for example>five micro devices] the defective microdevices that were marked or removed on the donor substrate, then these defective microdevices are determined as transfer impacted defects. A different action may be taken for a donor impacted defective devices vs. transfer impacted defective microdevices. For instance, donor-impacted defective microdevices may determine a new defect limit on acceptable donor substrate. In contrast, transfer impacted defective devices may require a stop on the transfer process to review process parameters.

A further embodiment is a method wherein the transfer process is repeated until the system substrate, the temporary substrate is fully populated, or the microdevices in the donor substrate are finished.

A further embodiment is an optimized transfer placement method that stores all the donor substrates with their marked or removed microdevices. The optimized transfer placement determines which donor substrates can be transferred to which system substrates. For example, the optimized transfer placement determines how many system substrates can be completed. Also, the optimized transfer placement determines which donor substrates can be transferred to which system substrate for the most efficient (fastest) and highest quality final display (defect pattern densities optimized for each final display.

In a further embodiment, the method determines wherein the defect is missing devices, and a position of the missing device is marked. For example, marking a microdevice may be (1) a marking address which is a row and column address stored in a database, or (2) a physical marking such as an inkjet color dot (or dots) that represents a color that can be easily found under a photoluminescent scan but may appear invisible (red, green, blue matrix) when looking at the display.

In a further embodiment, the method determines whether the marked micro device on a donor substrate is removed in advance. For example, a donor substrate removal algorithm is used to determine whether a donor substrate will be transferred. For example, a donor substrate removal algorithm determines if removal is because of (1) total defects on the donor substrate to a threshold or (2) a pattern of defective microdevices that may be sensitive to a user watching the final display, or (3) the donor substrate is defective in a series of defective donor substrates whereby a series of defective donor substrates could impact overall defect densities of multiple system substrates.

In a further embodiment, the method determines if the defect is a stocked micro device that is removed before transfer using destructive methods such as laser, etching, or mechanical pressure. For example, a laser can be used to ablate micro devices directly. In another example, a removal material is deposited on the donor substrate, and laser ablation is used to remove micro defect devices. The debris is scattered on the removal material, and the removable material is used. For example, laser-assisted chemical etches selectively remove defective micro devices with impact to surrounding micro devices and any related debris.

In a further embodiment, the method determines if the defect is the missing device. The micro device in the system substrate or temporary substrate is populated with another micro device or redirected to a spare microdevice. For example, a spool of micro devices within an insert tool can be aligned and activated to place a new usable micro device on the system substrate to replace the missing, defective micro device on the donor substrate.

In a further embodiment, the method of removal of a defective micros device is done by laser ablation or is removed by a directed high-pressure nozzle gas (air) or liquid (water) aimed at the defective micro device on the donor substrate or uses an elastomer glue to adhere and remove the defective micro devices on the donor substrate.

A method of transferring micro devices from donor substrate into system substrate method comprising, aligning a selected set of micro devices in donor substrate to the system substrate and transferring the selected set of micro devices into the system substrate and inspecting transferred microdevices for defects, and rectifying the defects that interfere with any of the following transfer cycles before that transfer cycle.

The preceding description of one or more embodiments of the invention has been presented for illustration and description. It is not intended to be exhaustive or to limit the invention to the precise form disclosed. Many modifications and variations are possible in light of the above teaching. It is intended that the scope of the invention be limited not by this detailed description but rather by the claims appended hereto.

1. A method to manage defects in a microdevice transfer process from a donor substrate, the method comprising:
transferring a set of microdevices to the system substrate or temporary substrate;
inspecting the transferred microdevices for defects wherein the inspection is either visual, photo luminance, or electrical luminance;
identifying a defect type wherein defects are either missing devices, devices stocked to the donor substrate permanently or devices that are not functional or have physical defects;
rectifying the identified defect based on a protocol; and
adjusting the transfer of a next set of microdevices to the system substrate or temporary substrate based on the protocol.

2. The method of claim 1, where machine learning is used to determine the quality of the donor substrate.

3. The method claim 1, an automated high-powered microscope system is used to determine the defects.

4. The method of claim 3, where multiple light sources are used with the automated high-powered microscope system and historical data to determine the quality of the donor substrate.

5. The method of claim 1, where a high-quality response map is used to analyze the donor substrates.

6. The method of claim 1, wherein the transfer includes aligning a selected set of micro devices on donor substrate with the system or temporary substrate;
transferring the selected set of micro devices to the system or temporary substrate; and
offsetting the donor substrate to the next transfer position.

7. The method of claim 6 uses an optimized placement algorithm to offset donor substrates.

8. The method of claim 6, where the transferred set of micro devices or donor substrate is inspected before the next transfer, uses a transfer quality algorithm.

9. The method of claim 1, wherein the transfer process is repeated till the system substrate, or the temporary substrate is fully populated, or the microdevices in the donor substrate are finished and use an optimized transfer placement.

10. The method of claim 1, wherein the defect is missing devices, and a position of the missing device is marked and is a marking address or a physical marking.

11. The method of claim 1, wherein a set associated with the missing micro device is marked during transfer and is not transferred and skipped.

12. The method of claim 1 wherein skipped the marked micro device set is removed in advance based upon a donor substrate removal algorithm.

13. The method of claim 1, wherein the defect is stocked micro device removed before transfer using destructive methods such as laser, etching, or mechanical pressure.

14. The method of claim 13, where the laser methods are any list or laser ablation, a laser using a removal material, or a laser-assisted chemical etch.

15. The method of claim 12, wherein the removed micro device is marked as a missing micro device and dealt with as a missing micro device defect.

16. The method of claim 1, wherein if the defect is an unfunctional or physical defect, the microdevice is either marked or removed and subsequently dealt with as marked or removed micro device defect type.

17. A method to manage defects in a micro device transfer process from a donor substrate to a system or temporary substrate, the method comprising:
aligning the donor substrate with a system or temporary substrate;
transferring selected micro devices to the system or temporary substrate;
bonding the transferred micro devices;
inspecting the donor substrate for defects wherein the inspection is either visual, photo luminance, or electrical luminance;
identifying a defect type wherein defects are either missing devices, devices stock to the donor substrate permanently, or devices that are not functional or have physical defects; and
rectifying the identified defect based on a protocol.

18. The method of claim 11, wherein the defect is missing the micro device in the system substrate or temporary substrate is populated with another micro device or redirected to a spare microdevice.

19. The method of claim 18 uses a spool of micro devices with an insert tool to replace missing microdevices on the system substrate.

20. The method of claim 12, wherein the defect is an extra microdevice then a donor substrate position is marked with a missing microdevice, and the process for missing microdevice in the donor substrate is repeated and the extra micro device is removed from the system or temporary substrate.

21. The method of claim 13, wherein the removal is done by laser, elastomer, pressurized gas (air), or liquid (water) methods.

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)
